(19) United States
(12) Patent Application Publication
(10) Pub. No.: US 2012/0194259 A1
(43) Pub. Date: Aug. 2, 2012

(54) TOUCH PANEL WITH INTERFERENCE SHIELDING ABILITY

(76) Inventor: Jane Hsu, Taoyuan County (TW)

(21) Appl. No.: 13/333,485

(22) Filed: Dec. 21, 2011

(30) Foreign Application Priority Data
Jan. 31, 2011 (TW) 100202258

(51) Int. Cl. H03K 17/94

(52) U.S. Cl. 327/517

(57) ABSTRACT

A touch panel with interference shielding ability mainly has a substrate with four edges and a transparent electrode formed on a top surface of the substrate. The substrate is rectangular and transparent. The transparent electrode has an active area with four edges. A routing region is defined between the edges of the active area and the edges of the substrate. A structure of compensating impedance is formed on the routing region. An anti-interference layer is formed on the top surface or a bottom surface corresponding to the routing region. The compensating impedance on the routing region forms a shield. The interference induced by directly touching the routing region is avoided for determination of coordinates of a touch point.

### BACKGROUND OF THE INVENTION

1. Field of the Invention

The present invention relates to a touch panel, and more particularly to a touch panel with interference shielding ability.

2. Description of Related Art

The types of the prevalent touch panels are classified as resistive touch panels and capacitive touch panels with different operating conditions. The types of the resistive touch panels are classified as a four-wire resistive touch panel, a five-wire resistive touch panel and an eight-wire resistive touch panel. The types of the capacitive touch panels are classified as a surface capacitive touch panel (SCT) and a projected capacitive touch panel (PCT). With the different sensing signals, the projected capacitive touch panel is considered as a digital touching technique, and the resistive touch panel and the surface capacitive touch panel are considered as an analog touching technique.

For example, the analog touch panel comprises a substrate and a transparent electrode layer. The substrate has a surface and the transparent electrode layer is formed on the surface of the substrate. The transparent electrode layer has four edges, and there are four resistive elements formed near the four edges. An active region enclosed by the resistive elements is formed. When a bias voltage is applied to the resistive elements, an equivalent potential appears within the active region. However, the impedance of the resistive elements is directly proportional to a distance between the resistive elements and the edges of the substrate. If the distance becomes shorter, the impedance will be smaller. The largest impedance appears at the middle position of the resistive elements. The equivalent potential within the active region is hardly formed because of the different impedances of the resistive elements. Therefore, the accuracy of determining the coordinates of a touch point is affected.

To solve the problem mentioned above, some methods such as to change the pattern of the resistive elements and to form a compensating impedance are disclosed. With reference to FIG. 9, Taiwan patent no. I246025, entitled “resistive touch panel with voltage compensation” comprises:

a rectangular substrate 510;

a uniform resistive surface 520 evenly formed on the rectangular substrate 510 and having four edges;

multiple resistive elements 530 formed near the edges of the uniform resistive surface 520 respectively;

multiple compensating elements 540 formed on the uniform resistive surface 520 and near the multiple resistive elements 530; and

a protection layer mounted on the uniform resistive surface 520, and covering the resistive elements 530 and the compensating elements 540.

The length of the compensating elements 540 is directly proportional to the distance between the compensating elements 540 and the edges of the uniform resistive surface 520. The interval between adjacent compensating elements 540 is inversely proportional to the distance between the compensating elements 540 and the edges of the uniform resistive surface 520. For example, with reference to FIG. 10, the length L1 of the compensating elements 540 located near the edges of the uniform resistive surface 520 is shorter than the length L2 of the middle compensating elements 540. The interval L3 between two adjacent compensating elements 540 located near the edges of the uniform resistive surface 520 is wider than the interval L4 between two middle adjacent compensating elements 540.

As a result, when a bias voltage is applied to the resistive elements 530, a rectangular electrical field is formed on the uniform resistive surface 520. The equivalent potential of the rectangular electrical field is uniformly distributed over the uniform resistive surface 520 because of the compensating impedance.

Above all, respectively forming the resistive elements 530 and the compensating elements 540 around the active region of a common touch panel can provide the uniform equivalent potential within the active region. However, the resistive elements 530 and the compensating elements 540 occupy a certain area near the edges of the substrate 510. When a user operates the active region, the resistive elements 530 and the compensating elements 540 will be easily touched. Although the protection layer covers the resistive elements 530 and the compensating elements 540, the accuracy of determining the coordinates of a touch point is still affected.

The same problems also occur in the projected capacitive touch panel. The projected capacitive touch panel mainly comprises one substrate or two substrates, multiple X-axis sensing wires and multiple Y-axis sensing wires. For a single substrate, both the X-axis sensing wires and the Y-axis sensing wires are formed on a surface of the same substrate and across each other. For dual substrates, the X-axis sensing wires and the Y-axis sensing wires are formed on the two substrates respectively and opposite to each other.

For either the single substrate or the dual substrates, there are multiple signal wires formed near the edges of the substrate to electrically connect to the sensing electrodes. Although the protection layer covers the signal wires, the signal wires will be affected when the user operates the touch panel.

For either a digital touch panel or an analog touch panel, the problem that the interference is induced on the wires on the substrate always exists.

### SUMMARY OF THE INVENTION

Therefore, an objective of the invention is to provide a touch panel with interference shielding ability. The wires on the touch panel have good shielding structure. Although the interference is induced from the touch of the human body or others, the interference against the determination of coordinates of a touch point is avoided by the shielding structure.

To achieve the foregoing objective, the touch panel with interference shielding ability comprises a substrate, a transparent electrode, a routing region, multiple resistive elements, multiple compensating elements, a bottom insulating layer and an anti-interference layer.

The substrate is rectangular and transparent and has a top surface, a bottom surface opposite to the top surface and four edges. The transparent electrode is formed on the top surface of the substrate and has an active area with four edges. The routing region is defined between the edges of the active area and the edges of the substrate. The multiple resistive elements are formed on the transparent electrode and within the routing region. The multiple compensating elements are formed within the routing region and near the resistive elements. The bottom insulating layer is formed on the routing region and covers the compensating elements and the resistive element. The anti-interference layer is conductive and is formed on the bottom insulating layer, wherein the position of the anti-interference layer corresponds to the position of the routing region.

To achieve the foregoing objective, another touch panel with interference shielding ability comprises a substrate, a transparent electrode, a routing region, multiple resistive elements, multiple compensating elements and an anti-interference layer.

The substrate is rectangular and transparent and has a top surface, a bottom surface opposite to the top surface and four edges. The transparent electrode is formed on the top surface of the substrate and has an active area with four edges. The routing region is defined between the edges of the active area and the edges of the substrate. The multiple resistive elements are formed on the transparent electrode and within the routing region. The multiple compensating elements are formed within the routing region and near the resistive elements. The anti-interference layer is conductive and is formed on the bottom surface of the substrate, wherein the position of the anti-interference layer corresponds to the position of the routing region.

Because the anti-interference layer is formed on the routing region or on the bottom surface of the substrate, the shielding structure for the resistive elements and the compensating elements is formed to achieve the purpose of anti interference.

To achieve the foregoing objective, another touch panel with interference shielding ability comprises a substrate, a routing region, multiple signal wires, a bottom insulating layer, at least one sensing layer and an anti-interference layer.

The substrate is rectangular and transparent and has a top surface, a bottom surface opposite to the top surface, four edges and an active area defined on the top surface of the substrate. The routing region is defined between the active area and the edges of the substrate. The multiple signal wires are formed on the routing region. The bottom insulating layer is formed on the routing region. The at least one sensing layer is formed on the top surface of the substrate and within the active area and comprises multiple electrode strings connected to the signal wires respectively. The anti-interference layer is conductive and formed on the top surface of the substrate, wherein the position of the anti-interference layer corresponds to the position of the routing region.

To achieve the foregoing objective, another touch panel with interference shielding ability comprises a substrate, a routing region, multiple signal wires, a bottom insulating layer, at least one sensing layer and an anti-interference layer.

The substrate is rectangular and transparent and has a top surface, a bottom surface opposite to the top surface, four edges and an active area defined on the top surface of the substrate. The routing region is defined between the active area and the edges of the substrate. The multiple signal wires are formed on the routing region. The bottom insulating layer is formed on the routing region. The at least one sensing layer is formed on the top surface of the substrate and within the active area and comprises multiple electrode strings connected to the signal wires respectively. The anti-interference layer is conductive and formed on the bottom surface of the substrate, wherein the position of the anti-interference layer corresponds to the position of the routing region.

To avoid the interference, the structure mentioned above could be applied to the projected capacitive touch panel to construct a shield on the routing region of the substrate.

### BRIEF DESCRIPTION OF THE DRAWINGS

FIG. 1 is a top view of a first embodiment of a touch panel with interference shielding ability in accordance with the present invention;

FIG. 2 is a cross-sectional view of the first embodiment of the touch panel with interference shielding ability in accordance with the present invention;

FIG. 3 is a cross-sectional view of a second embodiment of the touch panel with interference shielding ability in accordance with the present invention;

FIG. 4 is a cross-sectional view of a third embodiment of the touch panel with interference shielding ability in accordance with the present invention;

FIG. 5 is a top view of the third embodiment of the touch panel with interference shielding ability in accordance with the present invention;

FIG. 6 is a cross-sectional view of a fourth embodiment of the touch panel with interference shielding ability in accordance with the present invention;

FIG. 7 is a cross-sectional view of a fifth embodiment of the touch panel with interference shielding ability in accordance with the present invention;

FIG. 8 is a cross-sectional view of a sixth embodiment of the touch panel with interference shielding ability in accordance with the present invention;

FIG. 9 is a top view of a touch panel in accordance with the prior art.

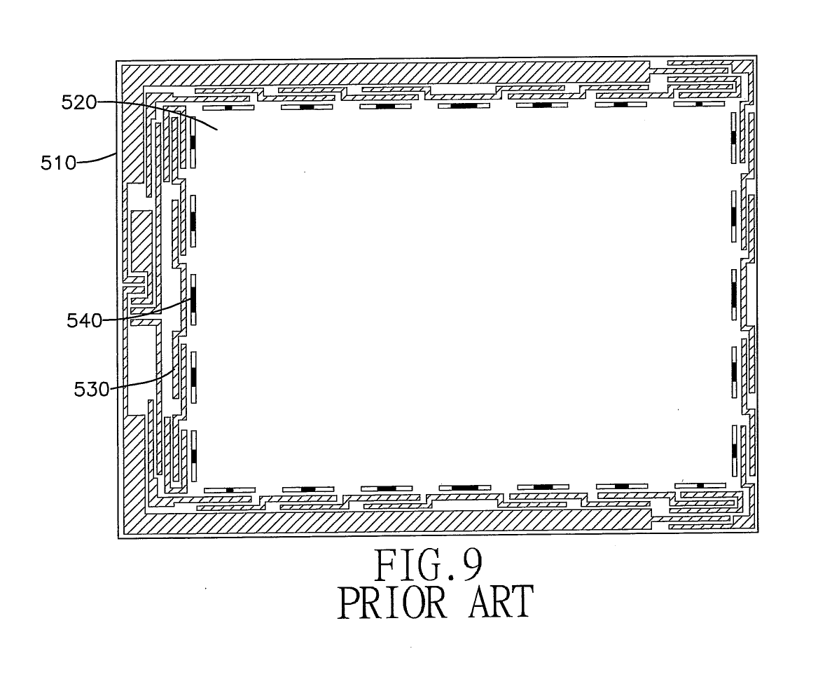

FIG. 10 is a perspective view of the compensating elements in accordance with the prior art.

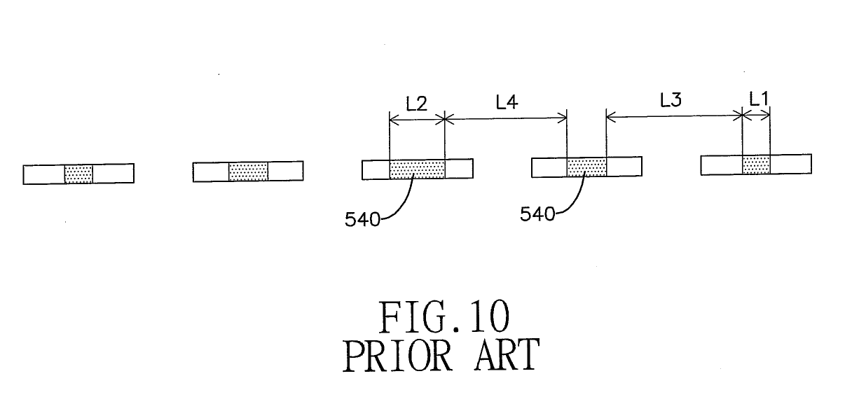

### DETAILED DESCRIPTION OF THE PREFERRED EMBODIMENT

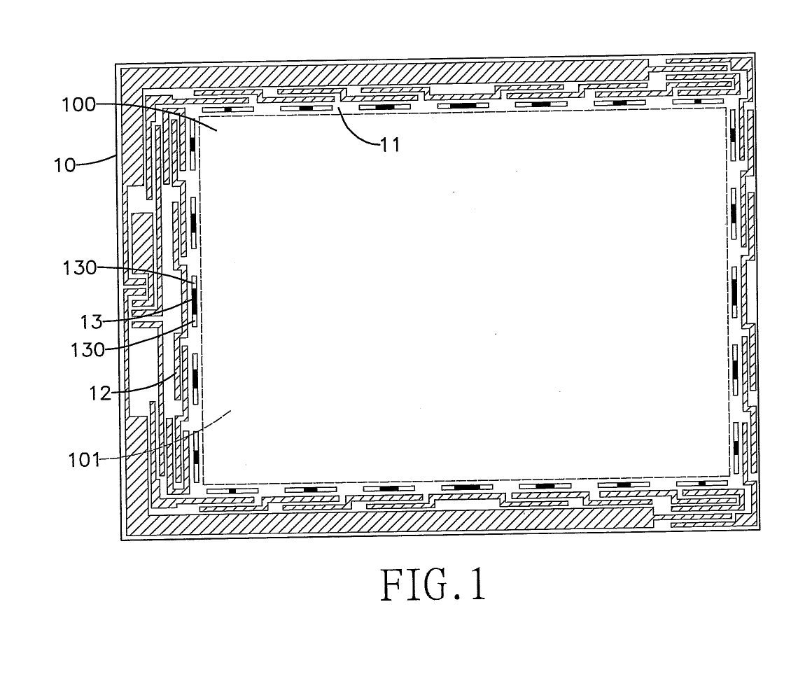

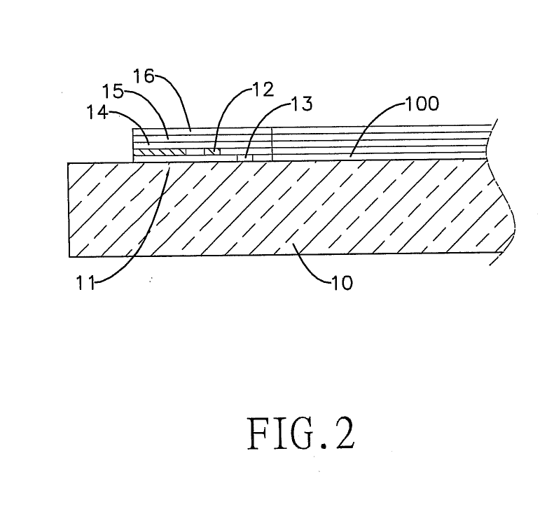

With reference to reference FIG. 1 and FIG. 2, a first embodiment applied to a resistive touch panel in accordance with the present invention mainly comprises a substrate 10, a transparent electrode (ITO) 100, a routing region 11, multiple resistive elements 12, multiple compensating elements 13, a bottom insulating layer 14 and an anti-interference layer 15.

The substrate 10 is transparent and rectangular and has a top surface, a bottom surface opposite to the top surface and four edges.

The transparent electrode 100 is formed on one surface of the substrate 10 and has four edges. The transparent electrode 100 has an active area 101, and the active area 101 has four edges. In the embodiment, the transparent electrode 100 is formed on the top surface of the substrate 10.

The routing region 11 is defined between the edges of the active area 101 and the edges of the substrate 10.

The multiple resistive elements 12 are formed on the transparent electrode 100 and within the routing region 11. The resistive elements 12 are formed by a screen-printing technique with silver paste, and arranged in a chain shape.

The multiple compensating elements 13 are formed within the routing region 11 and near the resistive elements 12. An available method to form the compensating elements 13 is to form multiple gaps 130 on a transparent conducive layer that forms the transparent electrodes 100, and is applied on the routing region 11. The gaps 130 are spaces where the transparent conducive layer is removed by etching or other methods. The remaining transparent conducive layer between the adjacent gaps 130 forms the compensating elements 13.

In order to achieve the purpose of anti-interference, with reference to FIG. 2, the bottom insulating layer 14 and the anti-interference layer 15 are formed on the routing region 11 sequentially.

The bottom insulating layer 14 is formed on the routing region 11 to cover the resistive elements 12 and the compensating elements 13. The anti-interference layer 15 is conductive and is formed on the bottom insulating layer 14. The position of the anti-interference layer 15 corresponds to the position of the routing region 11.

By forming the bottom insulating layer 14 and the anti-interference layer 15 on the routing region 11, the resistive elements 12 and the compensating elements 13 on the routing region 11 are efficiently separated from the outer environment. In addition, a top insulating layer 16 can be optionally formed on the anti-interference layer 15 to protect the anti-interference layer 15. The top insulating layer 16 and the bottom insulating layer 14 can be made of insulating ink.

A part of the top surface of the substrate 10 without the transparent electrode 100 may further form multiple signal wires and pads to electrically connect to the resistive elements 12. The signal wires and the pads are covered and separated from the outer environment by the bottom insulating layer 14, the anti-interference layer 15 and even the top insulating layer 16.

Because the bottom insulating layer 14 is made of insulating ink, the bottom insulating layer 14 provides fine insulating and separating effects for the resistive elements 12 and the compensating elements 13 at the routing region 11. In addition, the anti-inference layer 15 is formed on the bottom insulating layer 14 and serves as a fully metallic shield being used to connect to a ground. Taking advantage of this, the electrostatic effect or the capacitive effect caused by the touch from a human body is prevented. Then the accuracy of determining the coordinates of a touch point is ensured.

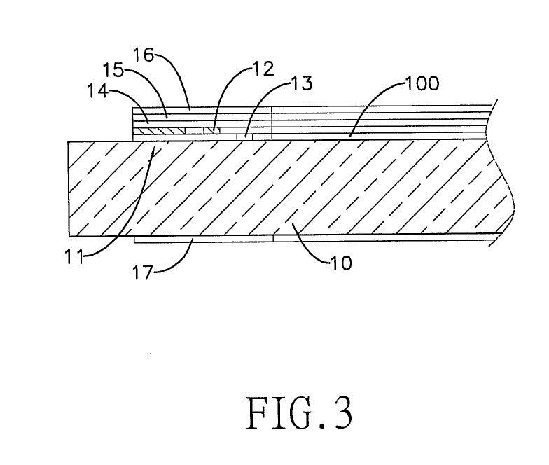

With reference to FIG. 3, a second embodiment in accordance with the present invention is disclosed. The structure of the second embodiment is similar to the first embodiment. The difference between the second embodiment and the first embodiment is that there is a second anti-inference layer 17 formed on the bottom surface of the substrate 10, and the position of the second anti-inference layer 17 corresponds to the position of the routing region 11 on the top surface of the substrate 10. The second anti-inference layer 17 is used to prevent the interference under the substrate 10.

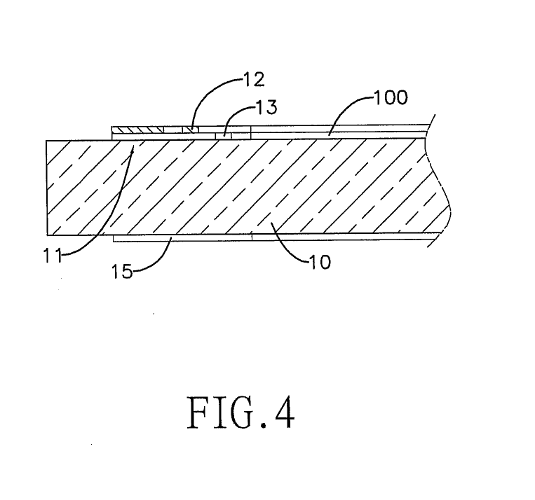

With reference to FIG. 4, a third embodiment in accordance with the present invention is disclosed. In the third embodiment, the anti-interference layer 15 is not formed on the top surface of the substrate 10. The anti-inference layer 15 is formed on the bottom surface of the substrate 10, and the position of the anti-inference layer 15 corresponds to the position of the routing region 11 on the top surface of the substrate 10. The third embodiment is used to isolate the interference under the substrate 10.

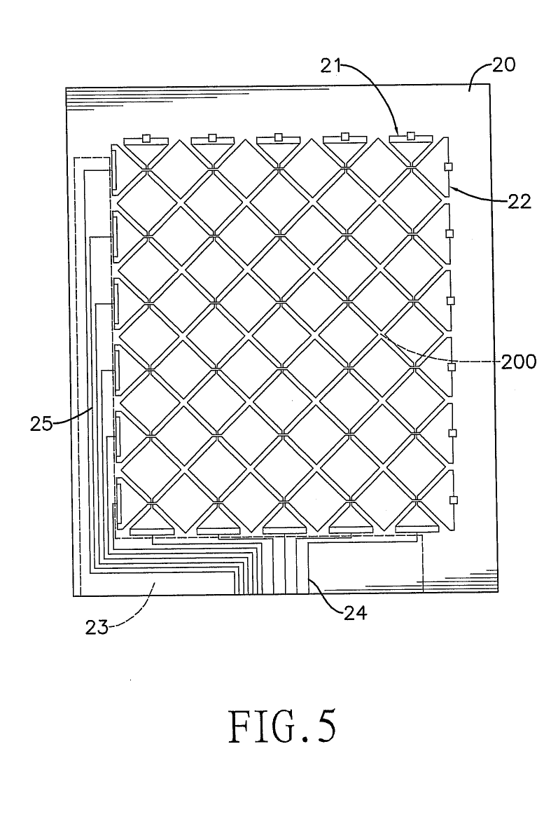

This invention is not only applied to the resistive touch panel, but is also applied to a projected capacitive touch panel. With reference to FIG. 5, the projected capacitive touch panel mainly comprises a substrate 20 and at least one sensing layer having multiple electrode strings 21, 22. The substrate 20 has a top surface, a bottom surface opposite to the top surface, four edges and an active area 200 defined on the top surface of the substrate 20. The electrode strings 21, 22 are formed on the top surface of the substrate 20 and within the active area 200. Each of the electrode strings 21, 22 is composed of multiple sensing electrodes connected in series. A routing region 23 is defined between the active area 200 and the edges of the substrate 20, and multiple signal wires 24, 25 are formed in the routing region 23. The signal wires 24, 25 are electrically connected to the electrode strings 21, 22. The embodiment in FIG. 5 is a projected capacitive touch panel with a single substrate. The projected capacitive touch panel with a single substrate mainly comprises a substrate 20, an X-axis sensing layer and a Y-axis sensing layer. The X-axis sensing layer has multiple X-axis electrode strings 21, and the Y-axis sensing layer has multiple Y-axis electrode strings 22. The Y-axis electrode strings 22 are arranged across the X-axis electrode strings 21.

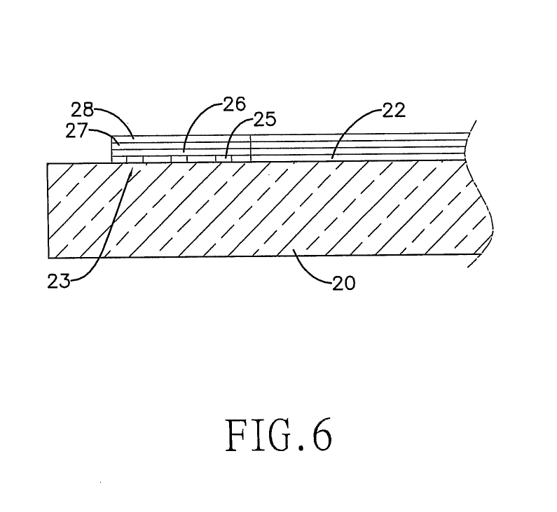

With reference to FIG. 6, a bottom insulating layer 26 is formed on the routing region 23 of the substrate 20. In this embodiment, an anti-interference layer 27 is formed on the bottom insulating layer 26. The anti-interference layer 27 is conductive and is used to electrically connect to a ground. In addition, there is a top insulating layer 28 formed on the anti-interference layer 27.

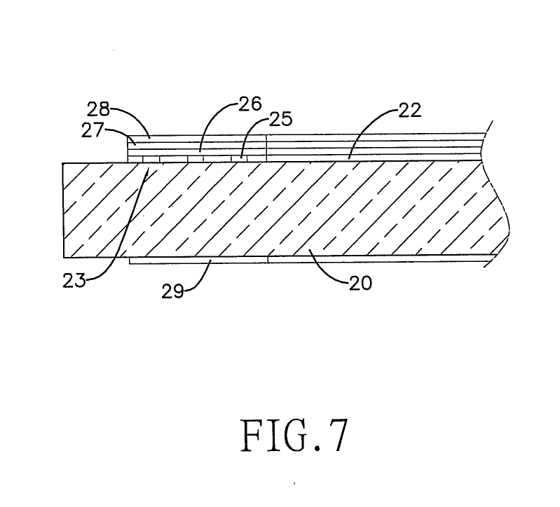

With reference to FIG. 7, in addition to the anti-interference layer 27 formed on the bottom insulating layer 26, a second anti-interference layer 29 is formed on the bottom surface of the substrate 20. The position of the second anti-interference layer 29 corresponds to the position of the routing region 23, and the second anti-interference layer 29 is used to electrically connect to the ground.

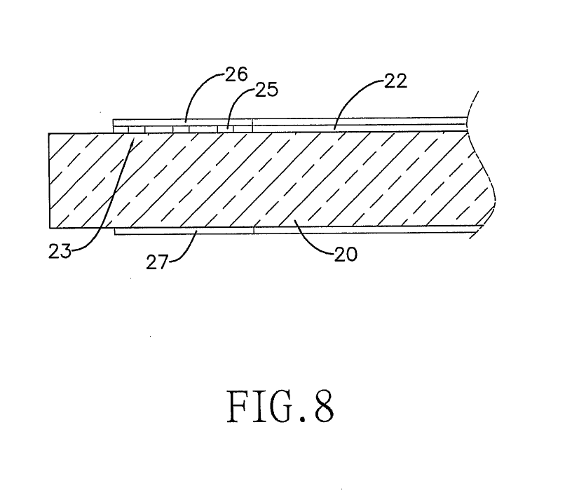

With reference to FIG. 8, there is only an anti-interference layer 27 formed on the bottom surface of the substrate 20. The position of the anti-interference layer 27 corresponds to the position of the routing region 23.

What is claimed is:

1. A touch panel with interference shielding ability comprising:
a substrate being rectangular and transparent and having:
a top surface;
a bottom surface opposite to the top surface; and
four edges;
a transparent electrode formed on the surface of the substrate and having an active area with four edges;
a routing region defined between the edges of the active area and the edges of the substrate;
multiple resistive elements formed on the transparent electrode and within the routing region;
multiple compensating elements formed within the routing region and near the resistive elements;
a bottom insulating layer formed on the routing region and covering the compensating elements and the resistive elements; and
an anti-interference layer being conductive and formed on the bottom insulating layer, wherein the position of the anti-interference layer corresponds to the position of the routing region.

2. The touch panel with interference shielding ability as claimed in claim 1, wherein a top insulating layer is formed on the anti-interference layer.

3. The touch panel with interference shielding ability as claimed in claim 1, wherein:
a second anti-inference layer is formed on the bottom surface of the substrate, and the position of the second anti-inference layer corresponds to the position of the routing region.

4. The touch panel with interference shielding ability as claimed in claim 2, wherein:
a second anti-inference layer is formed on the bottom surface of the substrate, and the position of the second anti-inference layer corresponds to the position of the routing region.

5. The touch panel with interference shielding ability as claimed in claim 3, wherein multiple signal wires are formed on a part of the top surface of the substrate.

6. The touch panel with interference shielding ability as claimed in claim 4, wherein multiple signal wires are formed on a part of the top surface of the substrate.

7. A touch panel with interference shielding ability comprising:
a substrate being rectangular and transparent and having:
a top surface;
a bottom surface opposite to the top surface; and
four edges;
a transparent electrode formed on the top surface of the substrate and having an active area with four edges;
a routing region defined between the edges of the active area and the edges of the substrate;
multiple resistive elements formed on the transparent electrode and within the routing region;
multiple compensating elements formed within the routing region and near the resistive elements;
an anti-interference layer being conductive and formed on the bottom surface of the substrate, wherein the position of the anti-interference layer corresponds to the position of the routing region.

8. The touch panel with interference shielding ability as claimed in claim 7, wherein multiple signal wires are formed on a part of the top surface of the substrate.

9. A touch panel with interference shielding ability comprising:
a substrate being rectangular and transparent and having
a top surface;
a bottom surface opposite to the top surface;
four edges; and
an active area defined on the top surface of the substrate;
a routing region defined between the active area and the edges of the substrate;
multiple signal wires formed in the routing region;
a bottom insulating layer formed on the routing region;
at least one sensing layer formed on the top surface of the substrate and within the active area and comprising multiple electrode strings connected to the signal wires respectively; and
an anti-interference layer being conductive and formed on the bottom insulating layer, wherein the position of the anti-interference layer corresponds to the position of the routing region.

10. The touch panel with interference shielding ability as claimed in claim 9, wherein
the sensing layer comprises:
multiple X-axis electrode strings; and
multiple Y-axis electrode strings arranged across the X-axis electrode strings.

11. The touch panel with interference shielding ability as claimed in claim 10 further comprising a top insulating layer formed on the anti-interference layer.

12. The touch panel with interference shielding ability as claimed in claim 10 further comprising a second anti-interference layer formed on the bottom surface of the substrate, wherein the position of the second anti-interference layer corresponds to the position of the routing region.

13. A touch panel with interference shielding ability comprising:
a substrate being rectangular and transparent and having
a top surface;
a bottom surface opposite to the top surface;
four edges; and
an active area defined on the top surface of the substrate;
a routing region defined between the active area and the edges of the substrate;
multiple signal wires formed on the routing region;
a bottom insulating layer formed on the routing region;
at least one sensing layer formed on the top surface of the substrate and within the active area and comprising multiple electrode strings connected to the signal wires respectively; and
an anti-interference layer being conductive and formed on the bottom surface of the substrate, wherein the position of the anti-interference layer corresponds to the position of the routing region.

14. The touch panel with interference shielding ability as claimed in claim 13, wherein
the sensing layer comprises:
multiple X-axis electrode strings; and
multiple Y-axis electrode strings arranged across the X-axis electrode strings.
